(19) United States
(12) Patent Application Publication
(10) Pub. No.: US 2020/0017990 A1
(43) Pub. Date: Jan. 16, 2020

(54) SiC-MONOCRYSTAL GROWTH CRUCIBLE

(71) Applicants: SHOWA DENKO K.K., Tokyo (JP); DENSO CORPORATION, Kariya-shi, Aichi (JP)

(72) Inventors: Shunsuke NOGUCHI, Hikone-shi (JP); Nobuyki OYA, Kariya-shi (JP)

(73) Assignees: Showa Denko K.K., Tokyo (JP); Denso Corporation, Kariya-shi, Aichi (JP)

(21) Appl. No.: 16/335,796

(22) PCT Filed: Jul. 31, 2017
(86) PCT No.: PCT/JP2017/027672

§ 371 Date: Mar. 22, 2019

(30) Foreign Application Priority Data
Sep. 23, 2016 (JP) 2016-185952

(51) Int. Cl. C30B 23/06; C30B 29/36; C23C 14/24; C23C 14/06; C01B 32/956

(52) U.S. Cl. CPC C30B 23/06; C30B 29/36; C01B 32/956; C23C 14/0635; C23C 14/243

(57) ABSTRACT

Provided is an SiC-monocrystal growth crucible that includes, at the interior thereof, a monocrystal installation part and a raw-material installation part, and that serves as a crucible for obtaining an SiC monocrystal by means of sublimation, wherein the gas permeability of a first wall of the crucible, which surrounds at least a portion of a first region positioned closer to the raw-material installation part relative to the monocrystal installation part, is lower than the gas permeability of a second wall of the crucible, which surrounds at least a portion of a second region positioned on the opposite side from the raw-material installation part relative to the monocrystal installation part.

### TECHNICAL FIELD

The present invention relates to a crucible for growing a SiC single crystal. Priority is claimed on Japanese Patent Application No. 2016-185952, filed Sep. 23, 2016, the content of which is incorporated herein by reference.

### BACKGROUND ART

Silicon carbide (SiC) has characteristic features. For example, compared to silicon (Si), the dielectric breakdown field of silicon carbide (SiC) is one order of magnitude larger, the band gap is three times larger, and the thermal conductivity is about three times higher. Therefore, silicon carbide (SiC) is expected to be applied to power devices, high frequency devices, high temperature operation devices, and the like.

As one of the methods for producing a SiC single crystal, the sublimation method is widely known. The sublimation method is a method in which a seed crystal made of a SiC single crystal is placed on a pedestal placed in a crucible made of graphite, sublimation gas sublimated from the raw material powder in the crucible is supplied to the seed crystal by heating the crucible, and the seed crystal is grown to a larger SiC single crystal. In the sublimation method, it is required to efficiently grow a high quality SiC single crystal.

For example, Patent Document 1 describes a crucible having a flow path formed axially symmetrically with respect to the central axis of the crucible. This crucible controls the gas flow generated due to the pressure difference inside and outside the crucible, enabling crystal growth of a high quality single crystal.

Further, for example, Patent Document 2 describes a crucible having a vaporized gas capturing trap on the side opposite to a raw material setting section with reference to a single crystal setting section where a single crystal is installed. This crucible specifies a place where a polycrystal is formed and prevents the formed polycrystal from coming into contact with the single crystal. The contact between the polycrystal and the single crystal causes a defect or the like. Therefore, when crystals are grown using the crucible, a high quality single crystal can be obtained.

Further, for example, Patent Document 3 describes a crucible in which the temperature distribution in the radial direction of the crucible is controlled. By controlling the temperature distribution in the radial direction of the crucible, deterioration of the quality of the portion to be expanded when the diameter of the single crystal is expanded is suppressed.

### CITATION LIST

### Patent Documents

[Patent Document 1] Japanese Unexamined Patent Application, First Publication No. 2008-115033

[Patent Document 2] Published Japanese Translation No. 2013-504513 of the PCT International Publication

[Patent Document 3] Japanese Unexamined Patent Application, First Publication No. 2002-12500

### SUMMARY OF INVENTION

### Technical Problem

However, in the crucible of Patent Document 1, since the source gas flows out from the portion where the flow path is formed, efficient single crystal growth cannot be performed. In the crucibles described in Patent Documents 2 and 3, although studies have been conducted to enhance the quality of single crystals, studies have not been sufficiently conducted to enhance the efficiency of crystal growth.

The present invention has been made in view of the above problems, and has an object of providing a crucible for growing a SiC single crystal capable of enhancing the growth efficiency of the SiC single crystal.

### Solution to Problem

The inventors of the present invention have found that the crystal growth efficiency of the SiC single crystal can be increased by generating a pressure difference in the crucible and giving a predetermined flow to the source gas.

That is, the present invention provides the following means to solve the above-mentioned problems.

(1) A crucible for growing a SiC single crystal according to a first aspect of the present invention has a single crystal setting section and a raw material setting section in its interior, wherein a gas permeability of a first wall of the aforementioned crucible surrounding at least a part of a first region located on the aforementioned raw material setting section side with reference to the aforementioned single crystal setting section is lower than a gas permeability of a second wall of the aforementioned crucible surrounding at least a part of a second region located on the opposite side of the aforementioned raw material setting section with reference to the aforementioned single crystal setting section.

(2) In the crucible for growing a SiC single crystal according to the above aspect, the gas permeability of the aforementioned first wall may be 90% or less of the gas permeability of the aforementioned second wall.

(3) In the crucible for growing a SiC single crystal according to the above aspect, it may be configured so that at least a part of the aforementioned first wall includes a gas shielding member.

(4) In the crucible for growing a SiC single crystal according to the above aspect, it may be configured so that the aforementioned gas shielding member is provided inside or on the outer periphery of the aforementioned first wall.

(5) In the crucible for growing a SiC single crystal according to the above aspect, the aforementioned gas shielding member may be any one of a metal, a metal carbide, and glassy carbon.

(6) In the crucible for growing a SiC single crystal according to the above aspect, it may be configured so that a thickness of the aforementioned first wall is greater than a thickness of the aforementioned second wall.

(7) In the crucible for growing a SiC single crystal according to the above aspect, it may be configured so that a density of the aforementioned first wall is higher than a density of the aforementioned second wall.

(8) In the crucible for growing a SiC single crystal according to the above aspect, the partition wall that partitions the aforementioned first region and the aforementioned second region may be a tapered guide that increases in diameter from the aforementioned single crystal setting section toward the raw material setting section.

### Advantageous Effects of Invention

The crucible for growing a SiC single crystal according to one aspect of the present invention can enhance the growth efficiency of the SiC single crystal.

### BRIEF DESCRIPTION OF DRAWINGS

FIG. 1 is a cross-sectional view schematically showing a cross section of an example of crucible for growing a SiC single crystal according to a first embodiment.

FIG. 2A is a cross-sectional view schematically showing a cross section of another example of the crucible for growing a SiC single crystal according to the first embodiment.

FIG. 2B is a cross-sectional view schematically showing a cross section of another example of the crucible for growing a SiC single crystal according to the first embodiment.

FIG. 3 is a cross-sectional view schematically showing a cross section of another example of the crucible for growing a SiC single crystal according to the first embodiment.

FIG. 4 is a cross-sectional view schematically showing a cross section of an example of crucible for growing a SiC single crystal according to a second embodiment.

FIG. 5 is a cross-sectional view schematically showing a cross section of an example of crucible for growing a SiC single crystal according to a third embodiment.

FIG. 6 is a cross-sectional view schematically showing a cross section of an example of crucible for growing a SiC single crystal according to a fourth embodiment.

### DESCRIPTION OF EMBODIMENTS

Hereinafter, a crucible for growing a SiC single crystal according to the present embodiment will be described in detail with reference to the drawings as appropriate. In the drawings used in the following description, characteristic portions and components may be shown in an enlarged manner in some cases for the sake of simplicity in order to facilitate understanding of the characteristics of the present invention, and the dimensional ratio or the like of each constituent element may be different from that employed in reality. Materials, dimensions, and the like exemplified in the following description are merely examples, and the present invention is not limited thereto and can be carried out with appropriate modifications without departing from the scope and spirit of the invention.

### (Crucible for Growing SiC Single Crystal)

### First Embodiment

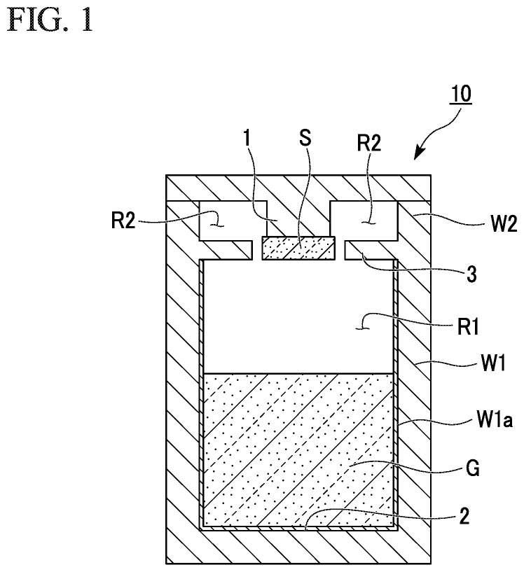

FIG. 1 is a cross-sectional view schematically showing a cross section of an example of crucible for growing a SiC single crystal according to a first embodiment. In FIG. 1, for ease of understanding, a single crystal S and a SiC raw material G are also shown.

A crucible for growing a SiC single crystal (SiC single crystal growing crucible) 10 is a crucible for producing a SiC single crystal by a sublimation method. The SiC single crystal growing crucible 10 includes a single crystal setting section 1 and a raw material setting section 2. In FIG. 1, the raw material setting section 2 is an inner bottom portion of the SiC single crystal growing crucible 10. The single crystal setting section 1 is arranged so as to face the raw material setting section 2.

The raw material setting section 2 stores the SiC raw material G The SiC raw material G is sublimated by heating and is recrystallized on the single crystal S provided in the single crystal setting section 1 so as to face the SiC raw material G.

The interior of the SiC single crystal growing crucible 10 is divided into two regions by a partition wall 3.

One is a first region R1 formed on the side of the raw material setting section 2 with reference to the single crystal setting section 1 and the other is a second region R2 formed on the opposite side of the raw material setting section 2 with reference to the single crystal setting section 1.

In FIG. 1, the first region R1 is a region surrounded by a bottom surface of the SiC single crystal growing crucible 10, a part of a side surface, and the partition wall 3. Further, the second region R2 is a region surrounded by an upper surface (lid portion) of the SiC single crystal growing crucible 10, a part of the side surface, the single crystal setting section 1, and the partition wall 3.

In FIG. 1, a first wall W1 forming the first region R1 has a gas shielding member W1a. On the other hand, a second wall W2 forming the second region R2 has no gas shielding member. Therefore, the gas permeability of the first wall W1 is lower than the gas permeability of the second wall W2.

Here, the gas permeability is an indicator for judging the amount of gas that can be permeated through the first wall W1 and the second wall W2 irrespective of the kind of material, and means the amount of gas per unit area that passes through the first wall W1 and the second wall when giving a constant pressure difference. The term is used in distinction from the gas permeability (gas permeability coefficient) specific to the material constituting the first wall W1 and the second wall W2.

The difference in gas permeability between the first wall W1 and the second wall W2 can be judged without measurement when the first wall W1 has the gas shielding member W1a as shown in FIG. 1. The gas shielding member W1a is constituted of a material (material hardly permeable to gases) whose gas permeability is several hundred times lower than that of the material (graphite or the like) constituting the second wall W2. Therefore, by having the gas shielding member W1a in part, it can be confirmed that the gas permeability of the first wall W1 is lower than the gas permeability of the second wall W2.

When the first wall W1 does not have the gas shielding member W1a, gas permeability is tested on the first wall W1 and the second wall W2 of the crucible, and the values obtained by dividing the obtained gas permeation amounts by the areas are compared. From this result, the difference in average values of the gas permeability can be directly obtained.

Here, the first wall W1 means a portion surrounding at least a part of the first region R1 and constituting an outer wall of the SiC single crystal growing crucible 10, and means the bottom portion and a part of the side wall of the SiC single crystal growing crucible 10. Further, the second wall W2 means a portion surrounding at least a part of the second region R2 and constituting an outer wall of the SiC single crystal growing crucible 10, and means the lid portion and a part of the side wall of the SiC single crystal growing crucible 10.

When the gas permeability of the first wall W1 is lower than the gas permeability of the second wall W2, the internal pressure of the first region R1 is higher than the internal pressure of the second region R2. The internal pressure difference inside the SiC single crystal growing crucible 10 generates a flow of the source gas sublimated from the SiC raw material G The source gas flows from the first region R1 with a high internal pressure to the second region R2 with a low internal pressure. That is, the source gas in the SiC single crystal growing crucible 10 is efficiently transported toward the single crystal S. Therefore, the growth of the single crystal S is promoted, and the SiC single crystal can be efficiently obtained.

In FIG. 1, although the gas shielding member W1a covers the entire inner surface of the first wall W1, it is not necessarily required to cover the entire surface, and the coverage may be partial. If at least a part of the first wall W1 is covered with the gas shielding member W1a, an internal pressure difference inside the SiC single crystal growing crucible 10 is generated, and the flow of the source gas from the first region R1 toward the second region R2 is generated.

Here, it is preferable that the difference between the gas permeability of the first wall W1 and the gas permeability of the second wall W2 is within a predetermined range. More specifically, the gas permeability of the first wall W1 is preferably 90% or less, more preferably 80% or less, and still more preferably 50% or less of the gas permeability of the second wall W2.

When the gas permeability of the first wall W1 is 90% or less of the gas permeability of the second wall W2, the difference in gas permeability between the first wall W1 and the second wall W2 is 10% or more. When the difference in gas permeability between the first wall W1 and the second wall W2 is 10% or more, a sufficient internal pressure difference is generated, and the source gas is efficiently transported to the single crystal S.

In order to increase the difference in gas permeability between the first wall W1 and the second wall W2, it is preferable that the gas permeability of the first wall W1 is as close as possible to zero. For example, when a metal is used for the gas shielding member W1a and the entire surface of the first wall W1 is covered, substantially no gas permeates.

On the other hand, in order to increase the difference in gas permeability between the first wall W1 and the second wall W2, it is also possible to increase the gas permeability of the second wall W2. However, if the gas permeability of the second wall W2 is too large, the source gas flows out from the inside of the SiC single crystal growing crucible 10, and the growth efficiency of the single crystal S decreases. For this reason, a crucible in which an opening is provided in a part of the second wall W2 and the sublimation gas flows out is not preferable. It should be noted that graphite is often used as a base material of a crucible used for growing silicon carbide. The gas permeability of graphite is about 10⁻¹ to 10⁻² cm²/sec, and by setting the second wall W2 in a sealed state using graphite, the absolute value of the gas permeability of the second wall W2 does not become too large.

The gas shielding member W1a is made of a material having a gas permeability lower than that of graphite. In general, in order to sublimate the SiC raw material G, it is necessary to set the temperature to about as high as 2,400° C. Therefore, most of the SiC single crystal growing crucible 10 is constituted of graphite. Since the gas shielding member W1a is made of a material having a gas permeability lower than that of graphite, it prevents the source gas from being released to the outside from inside the SiC single crystal growing crucible 10 via the first wall W1.

The gas shielding member W1a is preferably one of a metal, a metal carbide, and glassy carbon. Glassy carbon means non-graphitized carbon having both glass and ceramic properties.

The gas shielding member W1a containing these materials has an extremely high gas shielding property than that of graphite. It is generally said that graphite constituting a crucible used for crystal growth of SiC has a gas permeability of about 10⁻¹ to 10⁻² cm²/sec. On the other hand, it is said that the gas permeabilities of TaC coating film, which is an example of a metal carbide, and glassy carbon are 10⁻⁷ cm²/sec or less. Furthermore, it can be said that the metal film does not substantially permeate gases and has a gas permeability of 10⁻¹⁰ cm²/sec or less. By selecting the gas shielding member W1a according to the material constituting the second wall W2, the gas permeability of the first wall W1 can easily be lowered with respect to the gas permeability of the second wall W2.

It should be noted that the above gas permeability is a gas permeability of nitrogen gas under an environment having a predetermined pressure difference. Since the relative relationship of the gas permeability does not change greatly even if the absolute value of the numerical value changes, a selection can be made based on this indicator even under conditions of other gas species or different pressure difference.

The melting point of the metal or the metal carbide is preferably equal to or higher than 2,500° C. As the metal having a melting point of 2,500° C. or higher, for example, tantalum (Ta), osmium (Os), tungsten (W), molybdenum (Mo), rhenium (Re) and the like can be used. Further, as the metal carbide having a melting point of 2,500° C. or higher, for example, tantalum carbide (TaC), hafnium carbide (HfC), tungsten carbide (WC), titanium carbide (TiC), vanadium carbide (VC), molybdenum carbide (Mo2C) and the like can be used.

For example, when tantalum, tungsten and the like are used as the gas shielding member W1a as single metals, it is considered that tantalum carbide, tungsten carbide and the like are formed by carbon supplied from the source gas in the process of epitaxial growth. Therefore, it is preferable to use these metals as single metals because the labor and cost required for the carbonization treatment of metals can be reduced.

The thickness of the gas shielding member W1a is preferably 1 μm or more and 1,000 μm or less. Further, when a metal foil is used as the gas shielding member W1a, it is preferably 5 μm or more. The thickness of the gas shielding member W1a is obtained as an average value of film thicknesses at ten arbitrary points. The thickness of the gas shielding member W1a can be measured using a step gauge or the like.

If the thickness of the gas shielding member W1a is less than 1 μm, there may be a very thin portion of the gas shielding member W1a depending on unevenness in the thickness in the surface of the gas shielding member W1a. From such a portion, the sublimation gas leaks to the outside, and the internal pressure difference inside the SiC single crystal growing crucible 10 becomes small. Further, even if the thickness of the gas shielding member W1a is made too thick, the gas shielding effect does not change greatly. Therefore, if the thickness of the gas shielding member W1a is too thick, it leads to an increase in cost due to an increase in the amount of expensive metal used. When a metal foil is used as the gas shielding member W1a, it is difficult to obtain those having a thickness of less than 5 μm.

As described above, according to the SiC single crystal growing crucible 10 according to the first embodiment, it is possible to generate the flow of the source gas due to the internal pressure difference inside the crucible. As a result, it is possible to efficiently transport the source gas to the single crystal S provided in the single crystal setting section 1, and to efficiently grow the SiC single crystal.

The present embodiment is not necessarily limited to the above-described configuration, and various modifications can be made within a range that does not depart from the scope and spirit of the present invention.

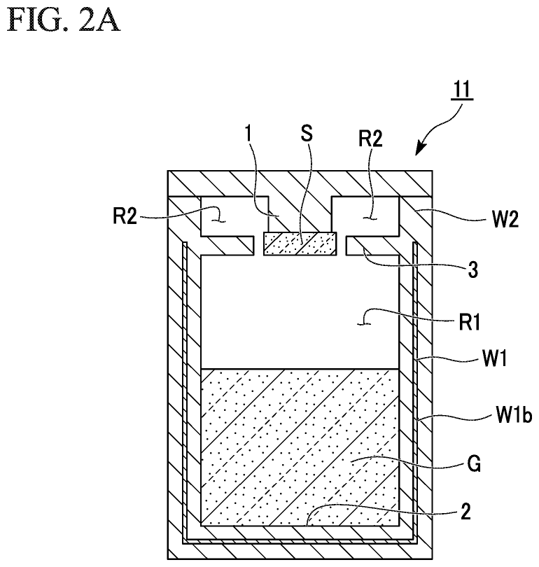

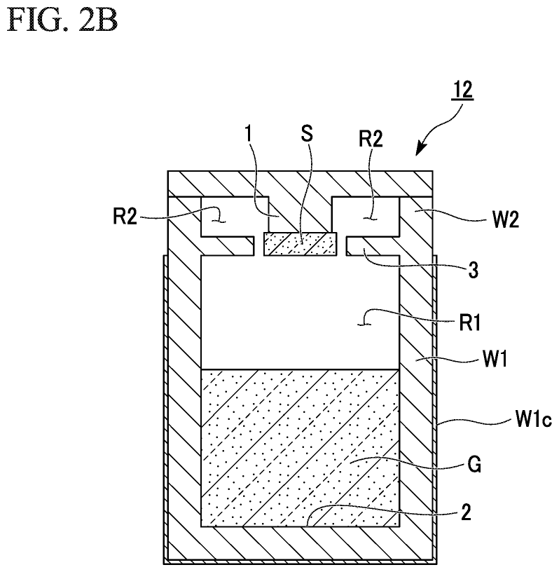

FIGS. 2A and 2B are cross-sectional views schematically showing cross section of other examples of the SiC single crystal growing crucible according to the first embodiment. In a SiC single crystal growing crucible 11 shown in FIG. 2A, a gas shielding member W1b is provided inside the first wall W1. Further, in a SiC single crystal growing crucible 12 shown in FIG. 2B, a gas shielding member W1c is provided outside the first wall W1. Other configurations are the same as those of the SiC single crystal growing crucible 10 described above, and are given the same reference numerals and signs.

In both configurations shown in FIGS. 2A and 2B, a difference in internal pressure occurs in the SiC single crystal growing crucibles 11 and 12 due to the difference in gas permeability. Therefore, the source gas is transported toward the single crystal S, and the SiC single crystal grows efficiently.

Further, in the SiC single crystal growing crucibles 11 and 12 shown in FIGS. 2A and 2B, the gas shielding members W1b and W1c are not in contact with the reaction space where the SiC single crystal is grown. Therefore, the inner surface of the crucible also functions as a carbon supply source, and it is possible to prevent the inside of the crucible from becoming a Si-rich environment. When the inside of the crucible becomes rich in Si, Si droplets and the like are generated when the SiC single crystal is grown from the seed crystal, and defects are likely to occur.

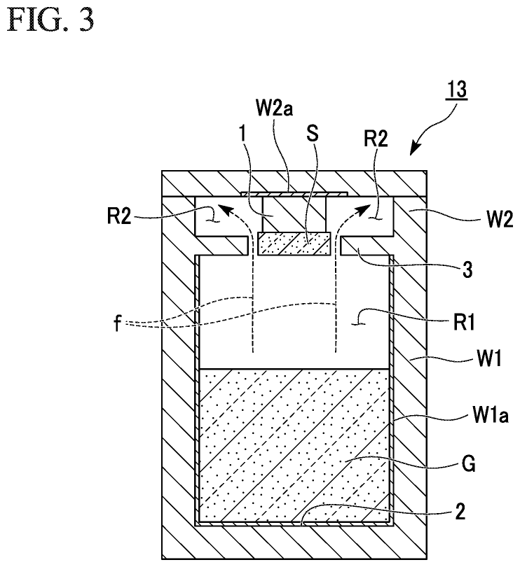

Further, FIG. 3 is a cross-sectional view schematically showing a cross section of another example of the SiC single crystal growing crucible according to the first embodiment. In a SiC single crystal growing crucible 13 shown in FIG. 3, a gas shielding member W2a is provided on a part of the second wall W2. Other configurations are the same as those of the SiC single crystal growing crucible 10 described above, and are given the same reference numerals and signs. The portion where the gas shielding member W2a is provided is a part of the second wall W2, and the average value of the gas permeability of the second wall W2 is larger than the average value of the gas permeability of the first wall W1.

The gas shielding member W2a is provided in a portion overlapping with the single crystal setting section 1 as seen from the SiC raw material G installed in the raw material setting section 2. For this reason, a flow f of the source gas flows from a boundary portion between the first region R1 and the second region R2 toward a portion where the gas shielding member W2a is not provided.

Therefore, the source gas which did not contribute to the crystal growth of the single crystal S becomes a polycrystal at the corner portion above the second region R2 shown in FIG. 3.

That is, a portion where the polycrystal grows becomes the position farthest from the single crystal S. When a polycrystal and a single crystal S to be grown come into contact, a defect or the like is generated in the single crystal S. Therefore, by separating the portion where the polycrystal grows from the single crystal S, it is possible to enhance the quality of the SiC single crystal to be grown.

### Second Embodiment

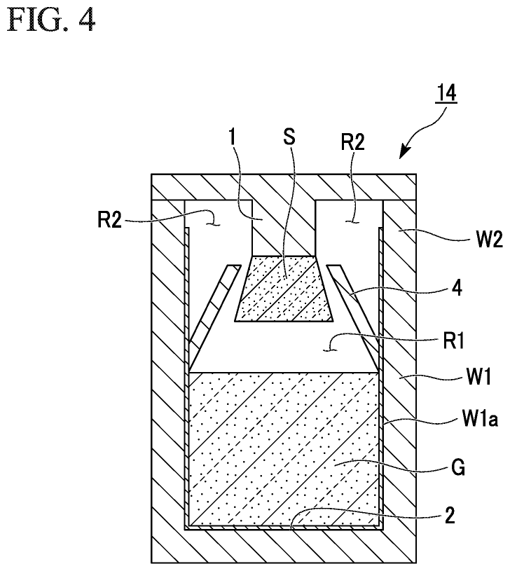

FIG. 4 is a schematic cross-sectional view schematically showing a cross section of an example of SiC single crystal growing crucible according to a second embodiment. A SiC single crystal growing crucible 14 according to the second embodiment is different from the SiC single crystal growing crucible 10 according to the first embodiment in that the partition wall that partitions the first region R1 and the second region R2 is a tapered guide 4 that increases in diameter from the single crystal setting section 1 toward the raw material setting section 2. Other configurations are the same as those of the SiC single crystal growing crucible 10 described above, and are given the same reference numerals and signs.

In the SiC single crystal growing crucible 14 shown in FIG. 4, the gas permeability of the first wall W1 is lower than the gas permeability of the second wall W2. Therefore, an internal pressure difference is generated between the first region R1 and the second region R2, and the source gas is efficiently supplied to the single crystal S. Further, the source gas flows along the tapered guide 4 and converges toward the single crystal S. Therefore, the source gas can be supplied to the single crystal S more efficiently.

Further, the source gas flows between the single crystal S provided on the single crystal setting section 1 and the tapered guide 4 according to the pressure difference. In the portion where the flow of the source gas is generated, crystal growth hardly occurs in a direction to block the flow of the source gas. That is, the flow path through which the source gas flows between the single crystal S and the tapered guide 4 is maintained even in the course of crystal growth of the single crystal S.

Therefore, even when the growth of the single crystal S grows, it is possible to avoid the contact between the polycrystal grown on the tapered guide 4 and the single crystal S. The polycrystal causes defects, homogeneous polymorphs and cracks by contacting the side surface of the single crystal S.

As described above, since the partition wall of the SiC single crystal growing crucible 14 according to the second embodiment is the tapered guide 4, the source gas can be supplied to the single crystal S more efficiently. Further, at this time, problems such as defects due to the contact between the polycrystal on the tapered guide and the single crystal S to be grown do not occur.

### Third Embodiment

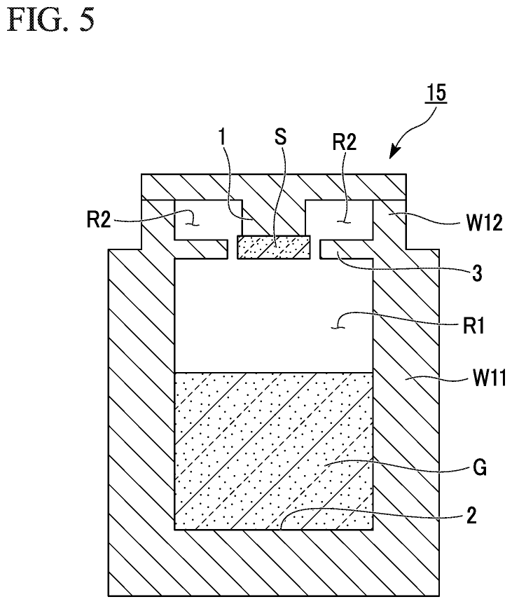

FIG. 5 is a schematic cross-sectional view schematically showing a cross section of an example of SiC single crystal growing crucible according to a third embodiment. A SiC single crystal growing crucible 15 according to the third embodiment is different from the SiC single crystal growing crucible 10 according to the first embodiment in that a first wall W11 does not have a gas shielding member, and the thickness of the first wall W11 is greater than the thickness of a second wall W12. Other configurations are the same as those of the SiC single crystal growing crucible 10 described above, and are given the same reference numerals and signs.

In the SiC single crystal growing crucible 15 according to the third embodiment, the thickness of the first wall W11 is greater than the thickness of the second wall W12. Here, the thicknesses of the first wall W11 and the second wall W12 mean the average thickness.

The difference in thickness between the first wall W11 and the second wall W12 generates a difference in gas permeability between the first wall W11 and the second wall W12. The gas permeability of the first wall W11 is lower than the gas permeability of the second wall W12. Therefore, an internal pressure difference is generated between the first region R1 and the second region R2, and a flow of the source gas from the first region R1 having a high internal pressure to the second region R2 having a low internal pressure is generated. In other words, the SiC single crystal growing crucible 15 promotes the growth of the single crystal S and can efficiently grow the SiC single crystal.

The thickness of the first wall W11 is preferably 1.1 times or more, and more preferably 1.5 times or more, of the thickness of the second wall W12. When the difference in thickness between the first wall W11 and the second wall W12 is 10% or more, a sufficient internal pressure difference occurs in the SiC single crystal growing crucible 15, and the SiC single crystal can be grown more efficiently.

In addition to the average thickness value, the minimum value of the thickness of the first wall W11 is preferably larger than the minimum value of the thickness of the second wall W12 by 10% or more. Here, the “minimum value of the thickness” means the thickness of the thinnest portion of the first wall W11 or the second wall W12.

When it is made of the same material, the gas permeability is highest at the thinnest portion. The difference between the source gas flowing out from the portion of the first wall W11 with the highest gas permeability and the source gas flowing out from the portion of the second wall W12 with the highest gas permeability occupies most of the source gas flowing from the first region R1 to the second region R2. Therefore, if the difference is 10% or more, the source gas can be sufficiently supplied to the SiC single crystal S present in the course from the first region R1 toward the second region R2.

### Fourth Embodiment

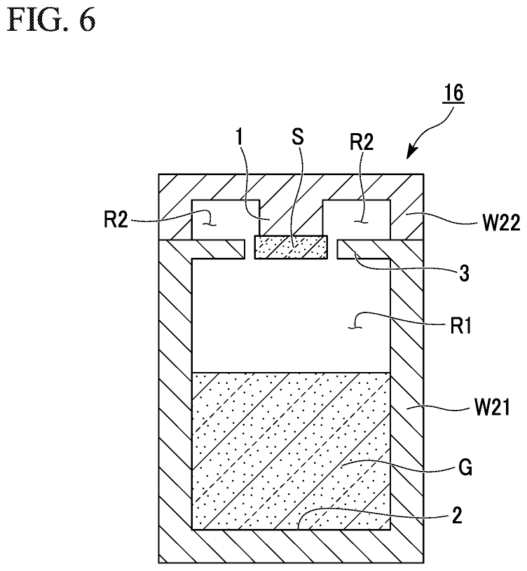

FIG. 6 is a schematic cross-sectional view schematically showing a cross section of a SiC single crystal growing crucible according to a fourth embodiment. A SiC single crystal growing crucible 16 according to the fourth embodiment is different from the SiC single crystal growing crucible 10 according to the first embodiment in that a first wall W21 does not have a gas shielding member, and the density of the first wall W21 is higher than the density of a second wall W22. Other configurations are the same as those of the SiC single crystal growing crucible 10 described above, and are given the same reference numerals and signs.

In the SiC single crystal growing crucible 16 according to the fourth embodiment, the density of the first wall W21 is higher than the density of the second wall W22. Here, the densities of the first wall W21 and the second wall W22 mean the average density.

Here, the average density is not limited to the case where it is made of the same material. The average density is obtained by measuring the weights of the first wall W21 and the second wall W22 and dividing the measured weights by their respective volumes. That is, high average density means that there are few voids in that portion, which means low gas permeability. For this reason, it does not depend on the types of materials of the first wall W21 and the second wall W22. On the other hand, it is preferable to use graphite having different densities for the first wall W21 and the second wall W22 in consideration of the adhesion of the interface, operating temperature, and the like.

The difference in density between the first wall W21 and the second wall W22 generates a difference in gas permeability between the first wall W21 and the second wall W22. The gas permeability of the first wall W21 is lower than the gas permeability of the second wall W22. Therefore, an internal pressure difference is generated between the first region R1 and the second region R2, and a flow of the source gas from the first region R1 having a high internal pressure to the second region R2 having a low internal pressure is generated. In other words, the SiC single crystal growing crucible 16 promotes the growth of the single crystal S and can efficiently grow the SiC single crystal.

The density of the first wall W21 is preferably 1.1 times or more, and more preferably 1.2 times or more, of the density of the second wall W22. When the difference in the density between the first wall W21 and the second wall W22 is 10% or more, a sufficient internal pressure difference occurs in the SiC single crystal growing crucible 16, and the SiC single crystal can be grown more efficiently.

Preferred embodiments of the present invention have been described in detail above. However, the present invention is not limited to these embodiments, and various changes and modifications can be made within the scope of the present invention described in the claims.

### REFERENCE SIGNS LIST

1: Single crystal setting section
2: Raw material setting section
3: Partition wall
4: Tapered guide
10, 11, 12, 13, 14, 15, 16: SiC single crystal growing crucible
R1: First region
R2: Second region
W1, W11, W21: First wall
W2, W12, W22: Second wall
W1a, W1b, W1c, W2a: Gas shielding member
S: Single crystal
G: SiC raw material

1. A crucible for growing a SiC single crystal which is a crucible for obtaining a SiC single crystal by a sublimation method,
the crucible comprising, in an interior thereof:
a single crystal setting section; and
a raw material setting section,
wherein a gas permeability of a first wall of said crucible surrounding at least a part of a first region located on said raw material setting section side with reference to said single crystal setting section is lower than a gas permeability of a second wall of said crucible surrounding at least a part of a second region located on an opposite side of said raw material setting section with reference to said single crystal setting section.

2. The crucible for growing a SiC single crystal according to claim 1, wherein a gas permeability of said first wall is 90% or less of a gas permeability of said second wall.

3. The crucible for growing a SiC single crystal according to either claim 1, wherein a part of said first wall comprises a gas shielding member.

4. The crucible for growing a SiC single crystal according to claim 3, wherein said gas shielding member is provided inside or on an outer periphery of said first wall.

5. The crucible for growing a SiC single crystal according to either claim 3, wherein said gas shielding member is any one of a metal, a metal carbide, and glassy carbon.

6. The crucible for growing a SiC single crystal according to claim 1, wherein a thickness of said first wall is greater than a thickness of said second wall.

7. The crucible for growing a SiC single crystal according to claim 1, wherein a density of said first wall is higher than a density of said second wall.

8. The crucible for growing a SiC single crystal according to claim 1, wherein a partition wall that partitions said first region and said second region is a tapered guide that increases in diameter from said single crystal setting section toward said raw material setting section.
